(19) United States
(12) Patent Application Publication
(10) Pub. No.: US 2026/0143752 A1
(43) Pub. Date: May 21, 2026

(54) THIN FILM TRANSISTOR, MANUFACTURING METHOD THEREOF, AND DISPLAY APPARATUS COMPRISING THE SAME

(71) Applicant: LG Display Co., Ltd., Seoul (KR)

(72) Inventors: Dohyung LEE, Paju-si (KR); JuHeyuck BAECK, Paju-si (KR); GaWon YANG, Paju-si (KR)

(73) Assignee: LG Display Co., Ltd., Seoul (KR)

(21) Appl. No.: 19/305,508

(22) Filed: Aug. 20, 2025

(30) Foreign Application Priority Data
Nov. 19, 2024 (KR) 10-2024-0164745

(51) Int. Cl. H10D 30/67; H10D 30/01; H10H 29/32; H10H 29/49

(52) U.S. Cl. CPC H10D 30/6755; H10D 30/031; H10H 29/32; H10H 29/49

(57) ABSTRACT

The disclosure provides a thin film transistor, a manufacturing method thereof, and a display apparatus comprising the same. One embodiment features a gate electrode overlapping at least a portion of the active layer, where the active layer includes first and second active layers spaced apart from each other. The first active layer includes, in vertical sequence, a first oxide semiconductor layer, a second oxide semiconductor layer, and a third oxide semiconductor layer. The second active layer includes, in vertical sequence, a fourth, a fifth, and a sixth oxide semiconductor layer. In the first active layer, the combined thickness of the first and second oxide semiconductor layers is 10% to 40% of the total thickness of the first active layer. In the second active layer, the combined thickness of the fifth and sixth oxide semiconductor layers is 10% to 40% of the total thickness of the second active layer.

### CROSS-REFERENCE TO RELATED APPLICATIONS

This application claims the benefit of priority of the Korean Patent Application No. 10-2024-0164745 filed on Nov. 19, 2024, which is hereby incorporated by reference as if fully set forth herein.

### BACKGROUND

### Technical Field

The present disclosure relates to a thin film transistor, a method for manufacturing the same, and a display apparatus including the same.

### Description of the Related Art

Since thin film transistors can be manufactured on glass or plastic substrates, they are widely used as switching elements or driving elements in display apparatuses such as liquid crystal display apparatuses or organic light emitting apparatuses.

The display apparatus may include, for example, a switching thin film transistor and a driver thin film transistor. Among these, it is advantageous for the driver thin film transistor to have a large s-factor for gray scale expression.

### BRIEF SUMMARY

In general, thin film transistors are designed with a small subthreshold swing factor (also referred to as a ‘s-factor’) in order to ensure favorable on-off switching characteristics. However, when such transistors are used as driving elements in display apparatuses, it becomes difficult to achieve accurate gray scale representation. To enable effective gray scale control in display driving applications, a thin film transistor with a large subthreshold swing factor is desirable. Furthermore, even when a large subthreshold swing factor is achieved, the transistor must also exhibit excellent current characteristics in the ON state to meet performance requirements.

Various embodiments of the thin film transistor disclosed herein include two active layers arranged in parallel, each comprising three vertically stacked oxide semiconductor sub-layers. The central sub-layer in each active layer has higher electron mobility than the outer sub-layers. Importantly, the position of the high-mobility sub-layer differs between the two active layers relative to the gate electrode—being closer to the gate in one layer and farther in the other. This configuration shifts the threshold voltages of the layers in opposite directions, resulting in an expanded threshold voltage range. As a result, the device achieves both a high subthreshold swing factor and strong ON-state current characteristics, which are typically difficult to achieve simultaneously.

The structure also includes specific control over physical dimensions. The combined thickness of the outer sub-layers is constrained to represent between 10% and 40% of the total active layer thickness, with the high-mobility sub-layer in one active layer measuring between three and five nanometers, and in the other between two and three nanometers. Additionally, the first active layer is wider than the second active layer, which increases the ON-state current while preserving precise analog control. The use of oxide semiconductor materials with different indium concentrations further allows adjustment of mobility and threshold behavior.

A manufacturing method is disclosed that enables the formation of these distinct active layers using shared process steps. By selectively applying a photoresist and etching oxide semiconductor material in a controlled sequence, the layers are constructed in parallel with different structural and compositional profiles. This approach supports integration of the device into a display panel, particularly in applications requiring fine gray scale control, such as organic light emitting diode displays, by combining precise threshold voltage modulation with reliable current-driving capability.

For example, one embodiment of the present disclosure is to provide a thin film transistor having a large s-factor in a period of threshold voltage and a large current value in an ON state by forming an active layer in a parallel structure.

One embodiment of the present disclosure is to provide a thin film transistor having a large s-factor in a period of threshold voltage and a large current value in an ON state by forming two active layers with different widths in a parallel structure.

One embodiment of the present disclosure is to provide a thin film transistor having a large s-factor in a period of threshold voltage and a large current value in an ON state by forming two active layers having different positions of high-mobility oxide semiconductor layers in a parallel structure.

Another embodiment of the present disclosure is to provide a display apparatus including such a thin film transistor.

One embodiment of the present disclosure provides a thin film transistor comprising an active layer; and a gate electrode overlapping at least a portion of the active layer, wherein the active layer includes a first active layer and a second active layer which are spaced apart from each other, wherein the first active layer includes a first oxide semiconductor layer; a second oxide semiconductor layer on the first oxide semiconductor layer; and a third oxide semiconductor layer on the second oxide semiconductor layer, and wherein the second active layer includes a fourth oxide semiconductor layer; a fifth oxide semiconductor layer on the fourth oxide semiconductor layer; and a sixth oxide semiconductor layer on the fifth oxide semiconductor layer, wherein a sum of a thickness of the first oxide semiconductor layer and a thickness of the second oxide semiconductor layer is 10% to 40% of a thickness of the first active layer, and a sum of a thickness of the fifth oxide semiconductor layer and a thickness of the sixth oxide semiconductor layer is 10% to 40% of a thickness of the second active layer.

The second oxide semiconductor layer may have higher mobility than the first oxide semiconductor layer and the third oxide semiconductor layer, and the fifth oxide semiconductor layer may have higher mobility than the fourth oxide semiconductor layer and the sixth oxide semiconductor layer.

The mobility of the second oxide semiconductor layer and the fifth oxide semiconductor layer can be 20 cm²/V·s to 100 cm²/V·s.

The mobility of the first oxide semiconductor layer, the third oxide semiconductor layer, the fourth oxide semiconductor layer, and the sixth oxide semiconductor layer can be 5 cm²/V·s to 15 cm²/V·s.

The second oxide semiconductor layer and the fifth oxide semiconductor layer are each made of a first oxide semiconductor material, and the first oxide semiconductor material may include at least one of an IO (InO)-based oxide semiconductor material having an In concentration of 30% to 50% relative to a total concentration of In and O on an atomic basis, an IGZO (InGaZnO)-based oxide semiconductor material having an In concentration of 30% or more relative to a total concentration of In, Ga, and Zn on an atomic basis, a FIZO (FInZnO)-based oxide semiconductor material, a FIGZO (FeInGaZnO)-based oxide semiconductor material, and an IZO (InZnO)-based oxide semiconductor material.

The first oxide semiconductor layer, the third oxide semiconductor layer, the fourth oxide semiconductor layer, and the sixth oxide semiconductor layer are each formed of a second oxide semiconductor material, and the second oxide semiconductor material may include at least one of an IGZO (InGaZnO)-based oxide semiconductor material having an In concentration of less than 30% relative to the total concentration of In, Ga, and Zn on an atomic basis, a GZTO (GaZnSnO)-based oxide semiconductor material, and a GZO (GaZnO)-based oxide semiconductor material.

The first active layer includes a first channel portion overlapping the gate electrode; a first connecting portion in contact with one side of the first channel portion; and a second connecting portion in contact with the other side of the first channel portion, and when the direction of a straight line connecting the first connecting portion and the second connecting portion at the shortest distance is a first direction and a direction perpendicular to the first direction is a second direction, a width of the first active layer may be greater than a width of the second active layer based on the second direction.

The thickness of the second oxide semiconductor layer may be greater than the thickness of the fifth oxide semiconductor layer.

The thickness of the second oxide semiconductor layer may be 3 nm or more and less than 5 nm, and the thickness of the fifth oxide semiconductor layer may be 2 nm or more and less than 3 nm.

Another embodiment of the present disclosure can provide a method for manufacturing a thin film transistor, including the steps of: preparing a base substrate having a first area and a second area; forming a second oxide semiconductor material layer on the second area, and then etching the second oxide semiconductor material layer; forming a first oxide semiconductor material layer on the first area and the second area; forming a photoresist pattern on the first area; simultaneously etching the first oxide semiconductor material layer and the second oxide semiconductor material layer using the photoresist pattern as a mask to form a first active layer and a second active layer; and forming a gate electrode on the first active layer and the second active layer.

The first oxide semiconductor material layer is disposed on the second oxide semiconductor material layer and can cover a side surface of the second oxide semiconductor material layer.

The photoresist pattern may not be disposed on the second area.

The first active layer includes a first oxide semiconductor layer; a second oxide semiconductor layer on the first oxide semiconductor layer; and a third oxide semiconductor layer on the second oxide semiconductor layer, and the second active layer includes a fourth oxide semiconductor layer; a fifth oxide semiconductor layer on the fourth oxide semiconductor layer; and a sixth oxide semiconductor layer on the fifth oxide semiconductor layer, and a sum of the thicknesses of the first oxide semiconductor layer and the second oxide semiconductor layer may be 10% to 40% of the thickness of the first active layer, and a sum of the thicknesses of the fifth oxide semiconductor layer and the sixth oxide semiconductor layer may be 10% to 40% of the thickness of the second active layer.

The shortest distance between the gate electrode and the fifth oxide semiconductor layer may be shorter than the shortest distance between the gate electrode and the second oxide semiconductor layer.

The method for manufacturing the thin film transistor further includes a step of forming a source electrode and a drain electrode, which are spaced apart from each other and respectively connected to an active layer comprising the first and second active layers, wherein the shortest distance between the source electrode and the fifth oxide semiconductor layer may be shorter than the shortest distance between the source electrode and the second oxide semiconductor layer.

The shortest distance between the drain electrode and the fifth oxide semiconductor layer may be shorter than the shortest distance between the drain electrode and the second oxide semiconductor layer.

Another embodiment of the present disclosure can provide a display apparatus including a thin film transistor.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a plan view of a thin film transistor according to one embodiment of the present disclosure.

FIG. 2 is a cross-sectional view taken along line Ia-Ia′ of FIG. 1.

FIG. 3 is a cross-sectional view taken along line Ib-Ib′ of FIG. 1.

FIG. 4 is a cross-sectional view taken along line Ic-Ic′ of FIG. 1.

FIG. 5 is a cross-sectional view of a thin film transistor according to another embodiment of the present disclosure.

FIG. 6 is a cross-sectional view of a thin film transistor according to another embodiment of the present disclosure.

FIG. 7 is a cross-sectional view of a thin film transistor according to another embodiment of the present disclosure.

FIG. 8 is a threshold voltage graph of a thin film transistor according to one embodiment of the present disclosure.

FIGS. 9A to 9G are plan views showing a manufacturing process of a thin film transistor according to one embodiment of the present disclosure.

FIGS. 10A to 10G are cross-sectional views showing a manufacturing process of a thin film transistor according to one embodiment of the present disclosure.

FIGS. 11A to 11G are cross-sectional views showing a manufacturing process of a thin film transistor according to one embodiment of the present disclosure.

FIG. 12 is a schematic diagram of a display apparatus according to another embodiment of the present disclosure.

FIG. 13 is a schematic diagram of one pixel (P) of FIG. 12.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

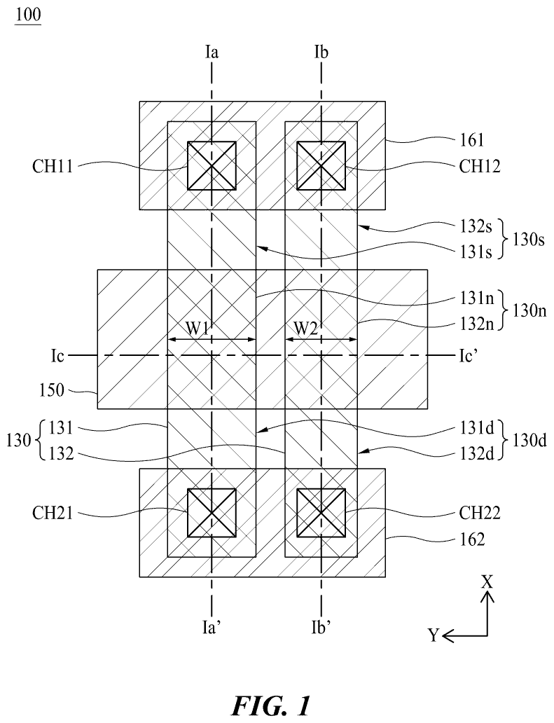

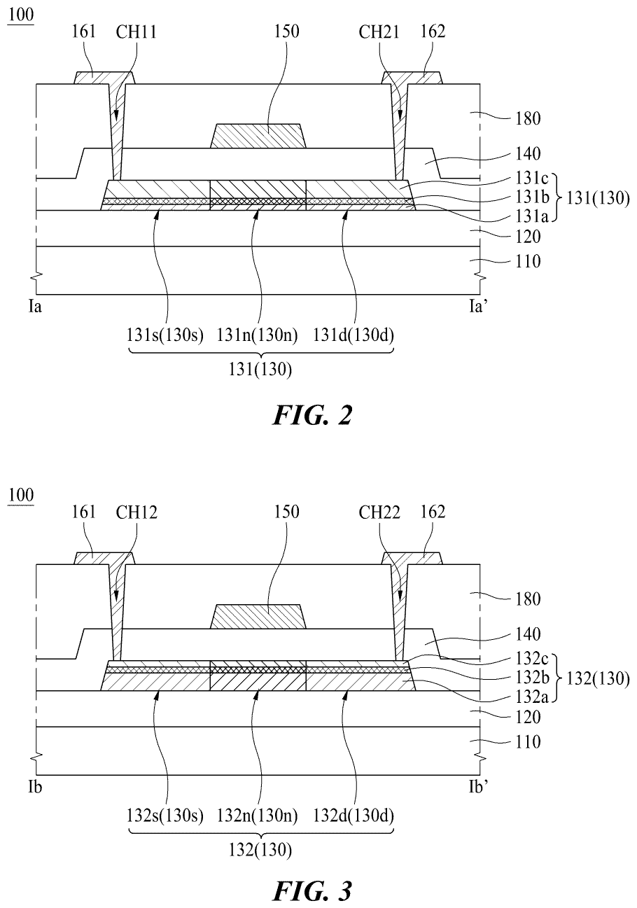

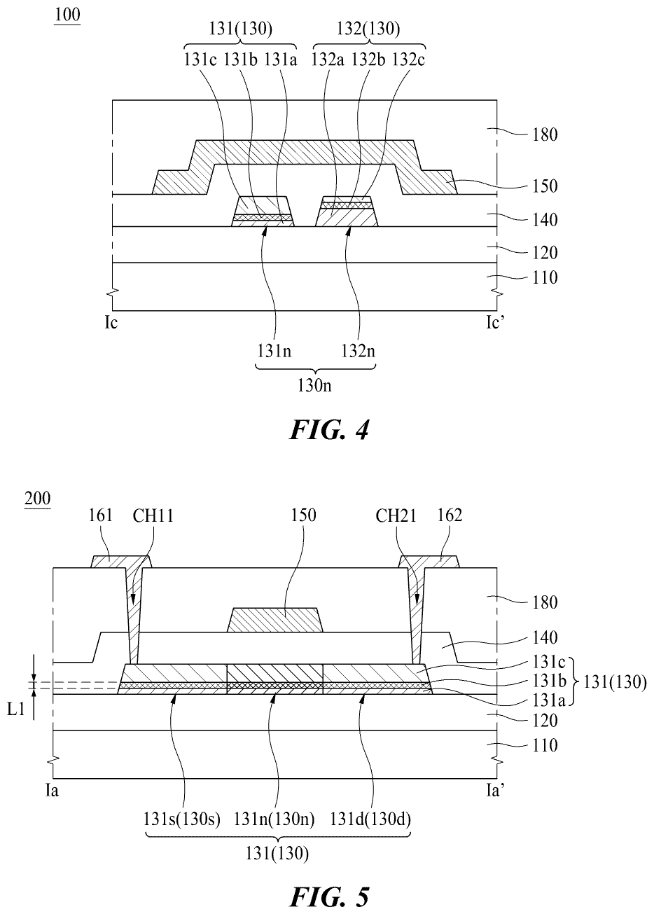

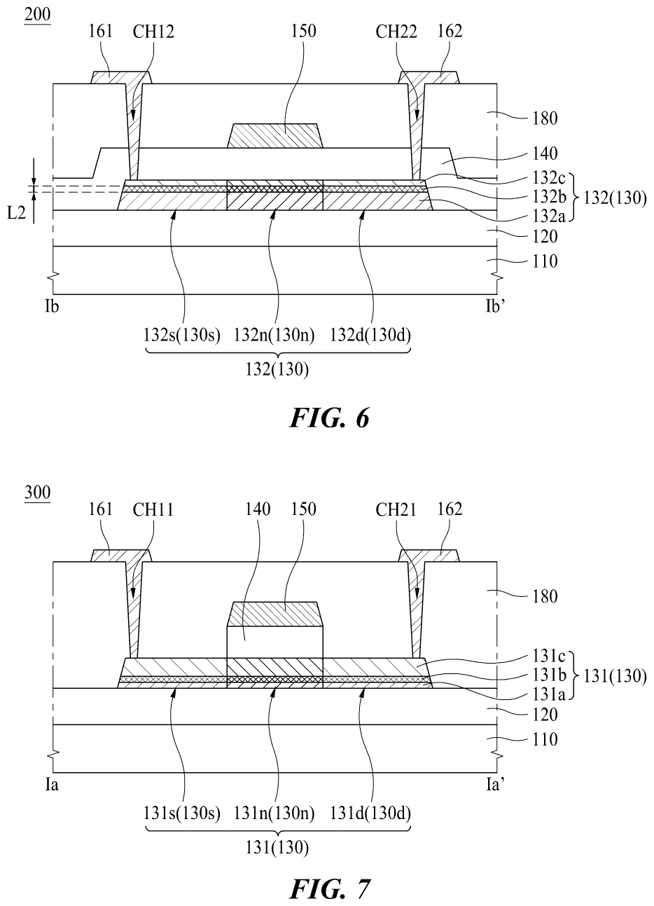

FIG. 1 is a plan view of a thin film transistor 100 according to one embodiment of the present disclosure. FIG. 2 is a cross-sectional view taken along line Ia-Ia′ of FIG. 1. FIG. 3 is a cross-sectional view taken along line Ib-Ib′ of FIG. 1. FIG. 4 is a cross-sectional view taken along line Ic-Ic′ of FIG. 5 is a cross-sectional view of a thin film transistor 200 according to another embodiment of the present disclosure. FIG. 6 is a cross-sectional view of a thin film transistor 200 according to another embodiment of the present disclosure.

A thin film transistor 100 according to one embodiment of the present disclosure includes an active layer 130 and a gate electrode 150.

The components of the thin film transistor 100 are described in detail below.

Glass or plastic may be used as the base substrate 110. A transparent plastic having flexible properties, such as polyimide, may be used as the plastic.

A light-blocking layer (not shown) may be disposed on the base substrate 110. The light-blocking layer (not shown) blocks light incident from the base substrate 110 and protects the active layer 130. If another structure serves as a light blocking structure, the light-blocking layer (not shown) may be omitted.

According to one embodiment of the present disclosure, a buffer layer 120 may be disposed on a base substrate 110. FIG. 2 illustrates a buffer layer 120 being disposed on a base substrate 110.

The buffer layer 120 has insulating properties and protects the active layer 130. The buffer layer 120 may include at least one of insulating silicon oxide (SiOx), silicon nitride (SiNx), and metal oxide.

Although FIG. 2 illustrates that the buffer layer 120 is a single layer, one embodiment of the present disclosure is not limited thereto and may include a plurality of layers. In addition, another layer may be disposed between the base substrate 110 and the buffer layer 120, and another layer may be disposed between the buffer layer 120 and the active layer 130.

According to one embodiment of the present disclosure, the active layer 130 is disposed on the buffer layer 120.

According to one embodiment of the present disclosure, the active layer 130 may include a first active layer 131 and a second active layer 132. For example, FIG. 1 illustrates a first active layer 131 and a second active layer 132 spaced apart from each other.

Referring to FIG. 1, the first active layer 131 and the second active layer 132 may be disposed to extend along the first direction X, and may be disposed spaced apart from each other based on the second direction Y.

According to one embodiment of the present disclosure, the active layer 130 may include a channel portion 130n, a source connecting portion 130s, and a drain connecting portion 130d.

According to one embodiment of the present disclosure, the first active layer 131 may include a first channel portion 131n, a first connecting portion 131s in contact with one side of the first channel portion 131n, and a second connecting portion 131d in contact with the other side of the first channel portion 131n. Referring to FIG. 1, the first channel portion 131n overlaps with the gate electrode 150, the first connecting portion 131s is connected to the source electrode 161, and the second connecting portion 131d is connected to the drain electrode 162.

According to one embodiment of the present disclosure, the second active layer 132 may include a second channel portion 132n, a third connecting portion 132s in contact with one side of the second channel portion 132n, and a fourth connecting portion 132d in contact with the other side of the second channel portion 132n. Referring to FIG. 1, the second channel portion 132n overlaps the gate electrode 150, the third connecting portion 132s is connected to the source electrode 161, and the fourth connecting portion 132d is connected to the drain electrode 162.

According to one embodiment of the present disclosure, the source connecting portion 130s may include a first connecting portion 131s and a third connecting portion 132s. The drain connecting portion 130d may include a second connecting portion 131d and a fourth connecting portion 132d.

The first connecting portion 131s, the second connecting portion 131d, the third connecting portion 132s, and the fourth connecting portion 132d can be formed by selectively conductorization for the active layer 130 made of a semiconductor material. According to one embodiment of the present disclosure, imparting conductivity to a specific portion of the active layer 130 so that it can function like a conductor is called selective conductorization.

For example, the active layer 130 can be selectively made conductorized by ion doping. As a result, the first connecting portion 131s, the second connecting portion 131d, the third connecting portion 132s, and the fourth connecting portion 132d can be formed. However, one embodiment of the present disclosure is not limited thereto, and the active layer 130 can also be selectively conductorized by other methods known in the art.

The first connecting portion 131s, the second connecting portion 131d, the third connecting portion 132s, and the fourth connecting portion 132d do not overlap with the gate electrode 150. The first connecting portion 131s, the second connecting portion 131d, the third connecting portion 132s, and the fourth connecting portion 132d have superior electrical conductivity and high mobility compared to the channel portion 130n. Therefore, the first connecting portion 131s, the second connecting portion 131d, the third connecting portion 132s, and the fourth connecting portion 132d can each function as a wiring.

Referring to FIG. 1, when the direction of the straight line connecting the first connecting portion 131s and the second connecting portion 131d at the shortest distance is referred to as the first direction X, the direction perpendicular to the first direction X may be referred to as the second direction Y. For example, the first direction X may be referred to as the length direction of the active layer 130, and the second direction Y may be referred to as the width direction of the active layer 130.

According to one embodiment of the present disclosure, the first active layer 131 and the second active layer 132 can be disposed parallel to the first direction X.

According to one embodiment of the present disclosure, the first active layer 131 may include a first oxide semiconductor layer 131a, a second oxide semiconductor layer 131b, and a third oxide semiconductor layer 131c. For example, FIG. 2 illustrates a state in which the second oxide semiconductor layer 131b is disposed on the first oxide semiconductor layer 131a, and the third oxide semiconductor layer 131c is disposed on the second oxide semiconductor layer 131b. For example, the second oxide semiconductor layer 131b may be disposed between the first oxide semiconductor layer 131a and the third oxide semiconductor layer 131c.

According to one embodiment of the present disclosure, the second active layer 132 may include a fourth oxide semiconductor layer 132a, a fifth oxide semiconductor layer 132b, and a sixth oxide semiconductor layer 132c. For example, FIG. 3 illustrates a state in which the fifth oxide semiconductor layer 132b is disposed on the fourth oxide semiconductor layer 132a, and the sixth oxide semiconductor layer 132c is disposed on the fifth oxide semiconductor layer 132b. For example, the fifth oxide semiconductor layer 132b may be disposed between the fourth oxide semiconductor layer 132a and the sixth oxide semiconductor layer 132c.

According to one embodiment of the present disclosure, the second oxide semiconductor layer 131b may have higher mobility than the first oxide semiconductor layer 131a and the third oxide semiconductor layer 131c, and the fifth oxide semiconductor layer 132b may have higher mobility than the fourth oxide semiconductor layer 132a and the sixth oxide semiconductor layer 132c.

For example, the mobility of the second oxide semiconductor layer 131b and the fifth oxide semiconductor layer 132b may be 20 cm²/V·s or more. Preferably, the mobility of the second oxide semiconductor layer 131b and the fifth oxide semiconductor layer 132b may be 20 cm²/V·s to 100 cm²/V·s. For example, the mobility of the first oxide semiconductor layer 131a, the third oxide semiconductor layer 131c, the fourth oxide semiconductor layer 132a, and the sixth oxide semiconductor layer 132c may be less than 20 cm²/V·s. Preferably, the mobility of the first oxide semiconductor layer 131a, the third oxide semiconductor layer 131c, the fourth oxide semiconductor layer 132 a, and the sixth oxide semiconductor layer 132c may be 5 cm²/V·s to 15 cm²/V·s.

When the mobility of the second oxide semiconductor layer 131b and the fifth oxide semiconductor layer 132b is less than 20 cm²/V·s, it may become difficult to significantly adjust the threshold voltage difference between the first active layer 131 and the second active layer 132 formed in parallel. As a result, a problem may occur in which the thin film transistor 100 according to the present disclosure does not have a large s-factor.

In addition, when the mobility of the second oxide semiconductor layer 131b and the fifth oxide semiconductor layer 132b is greater than 100 cm²/V·s, a problem may occur in which carriers in the first active layer 131 and the second active layer 132 become excessively large, making it difficult to accurately set the threshold voltage. In addition, in the worst case, a problem may occur in which the first active layer 131 and the second active layer 132 actually behave like conductors.

When the mobility of the first oxide semiconductor layer 131a, the third oxide semiconductor layer 131c, the fourth oxide semiconductor layer 132a, and the sixth oxide semiconductor layer 132c is less than 5 cm²/V·s, a problem may arise in which the current characteristics of the thin film transistor 100 become excessively low.

In addition, when the mobility of the first oxide semiconductor layer 131a, the third oxide semiconductor layer 131c, the fourth oxide semiconductor layer 132a, and the sixth oxide semiconductor layer 132c exceeds 15 cm²/V·s, a problem may occur in which the threshold voltage (Vth) of the thin film transistor 100 excessively shifts toward a negative (−) direction.

According to one embodiment of the present disclosure, the second oxide semiconductor layer 131b and the fifth oxide semiconductor layer 132b may each be formed of a first oxide semiconductor material. For example, the first oxide semiconductor material may include at least one of an IO (InO)-based oxide semiconductor material having an In concentration of 30% to 50% relative to the total concentration of In and O on an atomic basis, an IGZO (InGaZnO)-based oxide semiconductor material having an In concentration of 30% or more relative to the total concentration of In, Ga, and Zn on an atomic basis, a FIZO (FInZnO)-based oxide semiconductor material, a FIGZO (FeInGaZnO)-based oxide semiconductor material, and an IZO (InZnO)-based oxide semiconductor material.

For example, when the concentration of In is less than 30% of the total concentration of In and O in the IO (InO)-based oxide semiconductor material, the second oxide semiconductor layer 131b and the fifth oxide semiconductor layer 132b may not be sufficient to secure high mobility, and it may be difficult to implement an In concentration exceeding 50% of the total concentration of In and O in the IO (InO)-based oxide semiconductor material.

According to one embodiment of the present disclosure, the first oxide semiconductor layer 131a, the third oxide semiconductor layer 131c, the fourth oxide semiconductor layer 132a, and the sixth oxide semiconductor layer 132c may each be formed of a second oxide semiconductor material. For example, the second oxide semiconductor material may include at least one of an IGZO (InGaZnO)-based oxide semiconductor material having a concentration of In of less than 30% relative to the total concentration of In, Ga, and Zn on an atomic number basis, a GZTO (GaZnSnO)-based oxide semiconductor material, and a GZO (GaZnO)-based oxide semiconductor material.

According to one embodiment of the present disclosure, the sum of the thickness of the first oxide semiconductor layer 131a and the thickness of the second oxide semiconductor layer 131b may be 10% to 40% of the thickness of the first active layer 131. According to one embodiment of the present disclosure, the sum of the thickness of the fifth oxide semiconductor layer 132b and the thickness of the sixth oxide semiconductor layer 132c may be 10% to 40% of the thickness of the second active layer 132.

For example, in the case of the first active layer 131, the second oxide semiconductor layer 131b made of a high-mobility material may be disposed far from the gate electrode 150. For example, in the case of the second active layer 132, the fifth oxide semiconductor layer 132b made of a high-mobility material may be disposed close to the gate electrode 150. That is to say, when the thickness of the first active layer 131 and the second active layer 132 are the same, the fifth oxide semiconductor layer 132b is closer to the gate electrode 150 than the second oxide semiconductor layer 131b.

For example, the shortest distance between the gate electrode 150 and the fifth oxide semiconductor layer 132c may be shorter than the shortest distance between the gate electrode 150 and the second oxide semiconductor layer 131b.

For example, the shortest distance between the source electrode 161 and the fifth oxide semiconductor layer 132c may be shorter than the shortest distance between the source electrode 161 and the second oxide semiconductor layer 131b. For example, the shortest distance between the drain electrode 162 and the fifth oxide semiconductor layer 132c may be shorter than the shortest distance between the drain electrode 162 and the second oxide semiconductor layer 131b.

In general, it is advantageous for a driving thin film transistor to have a large s-factor for gray scale expression. The s-factor is explained below.

The s-factor (sub-threshold swing: s-factor) is obtained as the reciprocal value of the slope of the graph of the drain-source current versus the gate voltage of the thin film transistor 100 in the period of threshold voltage (Vth). The s-factor can be used, for example, as an indicator of the degree of change in the drain-source current versus the gate voltage in the period of threshold voltage (Vth) of the thin film transistor 100.

As the s-factor increases, the rate of change of drain-to-source current (I_{DS}) with respect to gate voltage in the period of threshold voltage (Vth) slows down.

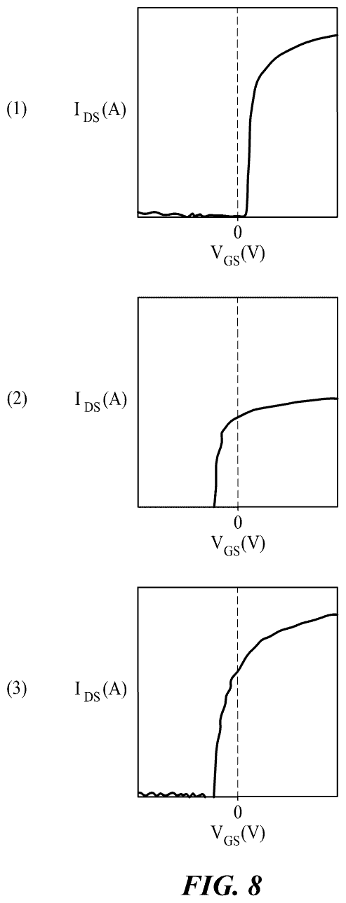

The s-factor can be explained, for example, by the current change graph shown in FIG. 8. FIG. 8 is a threshold voltage graph for a thin film transistor 100 according to the present disclosure. Specifically, FIG. 8 shows the gate voltage (V_{GS}) for drain-source current (I_{DS}) is displayed.

In the period of threshold voltage (Vth) of the graph shown in FIG. 8, the reciprocal of the slope of the drain-source current (I_{DS}) graph with respect to the gate voltage (V_{GS}) is the s-factor. If the slope of the graph is steep, the s-factor is small, and if the slope of the graph is small, the s-factor is large. If the s-factor is large, the rate of change of the drain-source current (I_{DS}) with respect to the gate voltage is smooth in the period of threshold voltage (Vth).

As the s-factor increases, the rate of change of the drain-source current (I_{DS}) with respect to the gate voltage in the period of threshold voltage (Vth) becomes more gradual, making it easier to control the magnitude of the drain-source current (I_{DS}) by adjusting the gate voltage (V_{GS}).

In a current-driven display device, for example, an organic light-emitting display device, the gray scale of a pixel can be controlled by adjusting the magnitude of a drain-source current (I_{DS}) of a driving thin film transistor. The magnitude of the drain-source current (I_{DS}) of the driving thin film transistor is determined by a gate voltage. Therefore, in a current-driven organic light-emitting display device, the larger the s-factor of the driving thin film transistor (Driving TR), the easier it is to adjust the gray scale of a pixel.

For example, the higher the position of the fifth oxide semiconductor layer 132b made of a high-mobility material in the second active layer 132, the more the high-mobility material is distributed at the interface of the second active layer 132 closer to the gate electrode 150. As a result, the thin film transistor 100 has a characteristic in which the threshold voltage (Vth) of the thin film transistor 100 shifts towards the negative (−) direction. As a result, the range of the period of threshold voltage (Vth) is widened, and the s-factor of the thin film transistor 100 increases.

For example, the lower the position of the second oxide semiconductor layer 131b made of a high-mobility material in the first active layer 131, the less the high-mobility material is distributed at the interface of the first active layer 131 closer to the gate electrode 150. As a result, the thin film transistor 100 has a characteristic in which the threshold voltage (Vth) of the thin film transistor 100 shifts towards the positive (+) direction.

According to one embodiment of the present disclosure, it may be difficult to implement such that the sum of the thickness of the first oxide semiconductor layer 131a and the thickness of the second oxide semiconductor layer 131b is less than 10% of the thickness of the first active layer 131.

In addition, when the sum of the thickness of the first oxide semiconductor layer 131a and the thickness of the second oxide semiconductor layer 131b exceeds 40% of the thickness of the first active layer 131, the second oxide semiconductor 131b may be positioned excessively close to the gate electrode 150, causing a problem in which the threshold voltage (Vth) of the first active layer 131 shifts towards the negative (−) direction.

According to one embodiment of the present disclosure, it may be difficult to implement such that the sum of the thickness of the fifth oxide semiconductor layer 132b and the thickness of the sixth oxide semiconductor layer 132c is less than 10% of the thickness of the second active layer 132.

In addition, when the sum of the thickness of the fifth oxide semiconductor layer 132b and the thickness of the sixth oxide semiconductor layer 132c exceeds 40% of the thickness of the second active layer 132, for example, the thickness of the sixth oxide semiconductor layer 132c may become excessively thick, and as a result, the fifth oxide semiconductor layer 132b may become excessively far from the gate electrode 150, and the thin film transistor 100 may not have the characteristic of shifting the threshold voltage (Vth) towards the negative (−) direction. In addition, for example, the thickness of the fifth oxide semiconductor layer 132b may become excessively thick, and as a result, the current characteristic in the second active layer 132 may excessively increase, and the s-factor of the thin film transistor 100 may decrease, which may cause a problem.

According to one embodiment of the present disclosure, based on the second direction Y, the width (W1) of the first active layer 131 may be greater than the width (W2) of the second active layer 132. According to one embodiment of the present disclosure, the width (width) of the active layer means the shortest length of the active layer with respect to the second direction Y.

In the past, a method of increasing the distance between the gate electrode and the channel region was applied to increase the s-factor of a thin film transistor. In this case, although the s-factor increased, there was a problem that the on-current of the thin film transistor decreased.

When the width (W1) of the first active layer 131 is greater than the width (W2) of the second active layer 132, the current flowing into the first active layer 131 increases. As a result, the thin film transistor 100 can have a large current value in the on state.

According to one embodiment of the present disclosure, the thickness (L1) of the second oxide semiconductor layer 131b may be greater than the thickness (L2) of the fifth oxide semiconductor layer 132b (see FIGS. 5 and 6).

When the thickness (L1) of the second oxide semiconductor layer 131b is greater than the thickness (L2) of the fifth oxide semiconductor layer 132b, the current flowing into the first active layer 131 increases. As a result, the thin film transistor 200 can have a large current value in the on state.

In other words, since the thin film transistor according to the present disclosure has a first active layer 131 and a second active layer 132, it can have excellent (on) current characteristics and a large s-factor.

For example, the thickness (L1) of the second oxide semiconductor layer 131b may be 3 nm or more and less than 5 nm, and the thickness (L2) of the fifth oxide semiconductor layer 132b may be 2 nm or more and less than 3 nm.

For example, when the thickness (L1) of the second oxide semiconductor layer 131b is less than 3 nm, the thin film transistor 200 may not have a large current value in the on state. When the thickness (L1) of the second oxide semiconductor layer 131b is 5 nm or more, a problem of the threshold voltage (Vth) in the first active layer 131 shifting towards the negative (−) direction may occur.

For example, when the thickness (L2) of the fifth oxide semiconductor layer 132b is less than 2 nm, the thin film transistor 200 may not have the characteristic of the threshold voltage (Vth) shifting towards the negative (−) direction. When the thickness (L2) of the fifth oxide semiconductor layer 132b is 3 nm or more, the current characteristic in the second active layer 132 may excessively increase, and the s-factor of the thin film transistor 200 may decrease, which may cause a problem.

According to one embodiment of the present disclosure, a gate insulating film 140 is disposed on an active layer 130. Specifically, the gate insulating film 140 is disposed between the active layer 130 and a gate electrode 150.

According to one embodiment of the present disclosure, the gate insulating film 140 can cover the entire upper surface of the active layer 130. FIGS. 2, 3, and 4 illustrate that the gate insulating film 140 covers the entire upper surface of the active layer 130. However, the present disclosure is not limited thereto, and the gate insulating film 140 can expose the first connecting portion 131s and the second connecting portion 131d of the active layer 130 (see FIG. 7). FIG. 7 corresponds to the drawing of FIG. 2, and although omitted in the drawing, the gate insulating film 140 can expose the third connecting portion 132s and the fourth connecting portion 132d of the active layer 130.

The gate insulating film 140 may include at least one of silicon oxide, silicon nitride, and metal oxide. The gate insulating film 140 may have a single film structure or a multilayer film structure. The gate insulating film 140 protects the active layer 130.

According to one embodiment of the present disclosure, a gate electrode 150 may be disposed on a gate insulating film 140.

According to one embodiment of the present disclosure, the gate electrode 150 may overlap with the active layer 130. For example, referring to FIG. 1, the gate electrode 150 may overlap with the channel portion 130n of the active layer 130. For example, the gate electrode 150 may overlap with the first channel portion 131n of the first active layer 131 and the second channel portion 132n of the second active layer 132.

The gate electrode 150 may include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The gate electrode 150 may also have a multilayer film structure including at least two conductive films having different physical properties.

An interlayer insulating film 180 is disposed on the gate electrode 150. The interlayer insulating film 180 is an insulating layer made of an insulating material. Specifically, the interlayer insulating film 180 may be made of an organic material, an inorganic material, or a laminate of an organic material layer and an inorganic material layer.

A source electrode 161 and a drain electrode 162 are disposed on an interlayer insulating film 180. The source electrode 161 and the drain electrode 162 are spaced apart from each other and are connected to a source connecting portion 130s and a drain connecting portion 130d, respectively. Specifically, the source electrode 161 is connected to a first connecting portion 131s and a third connecting portion 132s through a first-first contact hole (CH11) and a first-second contact hole (CH12) formed in the interlayer insulating film 180. The drain electrode 162 is connected to a second connecting portion 131d and a fourth connecting portion 132d through a second-first contact hole (CH21) and a second-second contact hole (CH22) formed in the interlayer insulating film 180.

The source electrode 161 and the drain electrode 162 may each include at least one of molybdenum (Mo), aluminum (Al), chromium (Cr), gold (Au), titanium (Ti), nickel (Ni), neodymium (Nd), copper (Cu), and alloys thereof. The source electrode 161 and the drain electrode 162 may each be formed of a single layer made of a metal or an alloy of metals, or may be formed of two or more multilayers.

FIG. 8 is a threshold voltage graph of a thin film transistor 100 according to one embodiment of the present disclosure. The threshold voltage graph for the thin film transistor is represented as a graph of drain-source current (I_{DS}) versus gate voltage (V_{GS}).

Graph (3) in FIG. 8 is a threshold voltage graph for a thin film transistor having the same structure as the thin film transistor 100 of FIG. 1. Graph (1) is a threshold voltage graph for a thin film transistor having only a first active layer 131. Graph (2) is a threshold voltage graph for a thin film transistor having only a second active layer 132.

Referring to FIG. 8, it can be confirmed that the thin film transistor having the first active layer 131 has excellent on current characteristics, but has a characteristic in which the threshold voltage shifts towards the positive (+) direction, and the current flowing through the thin film transistor increases rapidly in the threshold voltage range, thereby having a small s-factor.

On the other hand, it can be confirmed that the thin film transistor having the second active layer 132 has a low on current characteristic, but has a threshold voltage shifted towards the negative (−) direction, and the current flowing through the thin film transistor increases rapidly in the period of the threshold voltage, so that it has a small s-factor.

A thin film transistor (graph (3)) according to one embodiment of the present disclosure can have excellent (on) current characteristics by having a first active layer 131 and can have a large s-factor by having a second active layer 132.

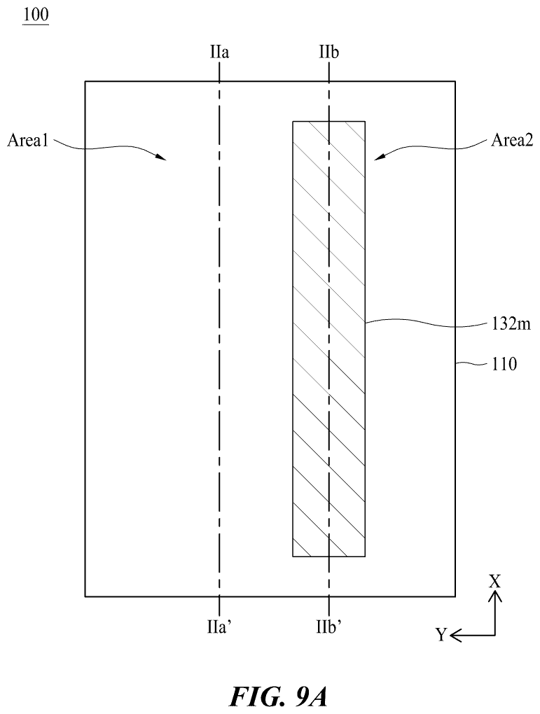

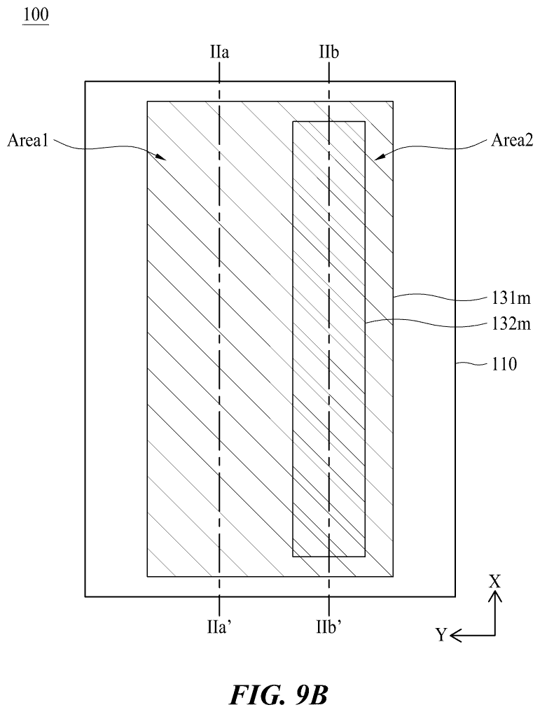

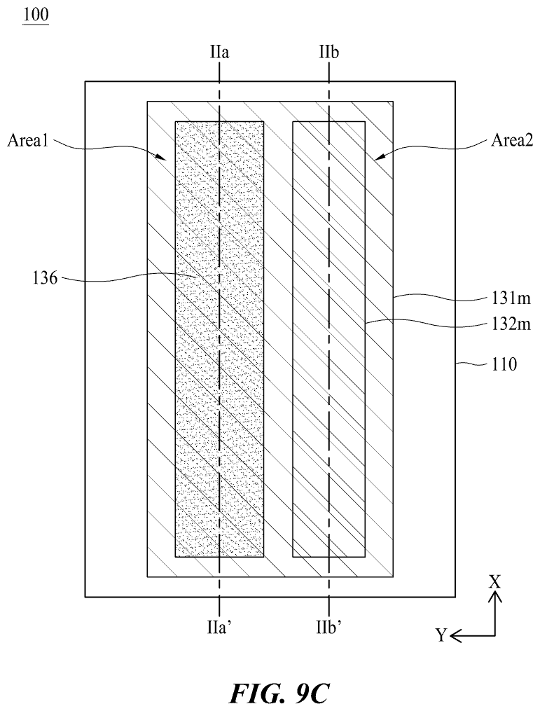

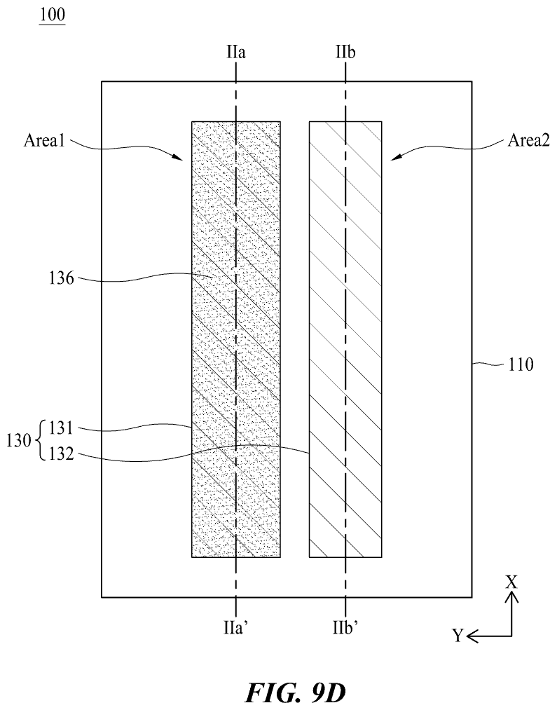

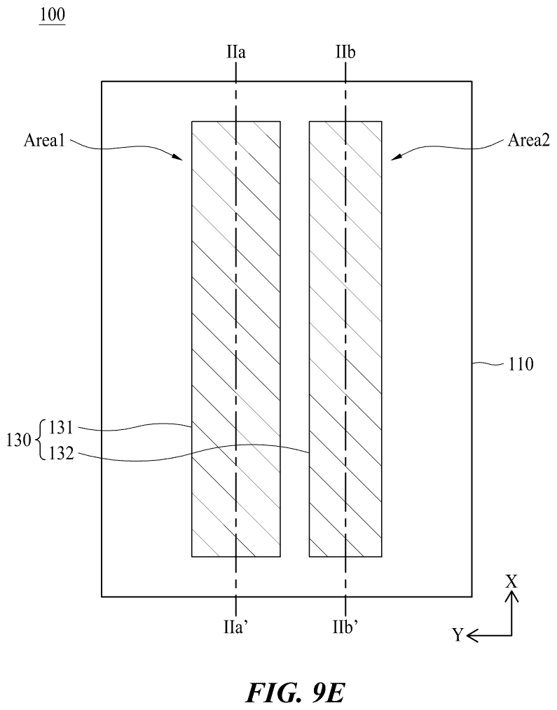

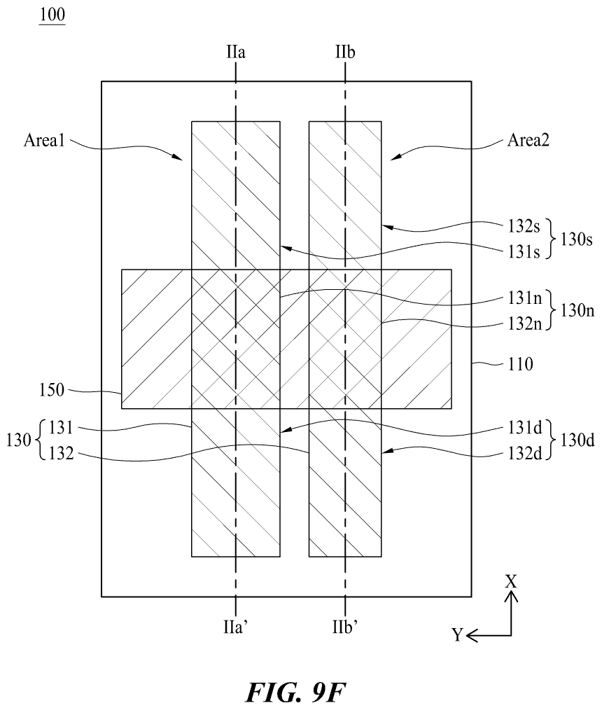

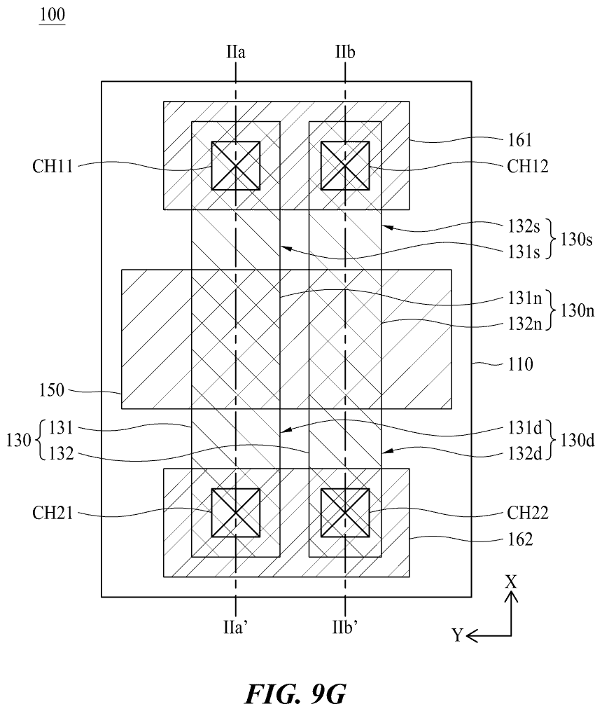

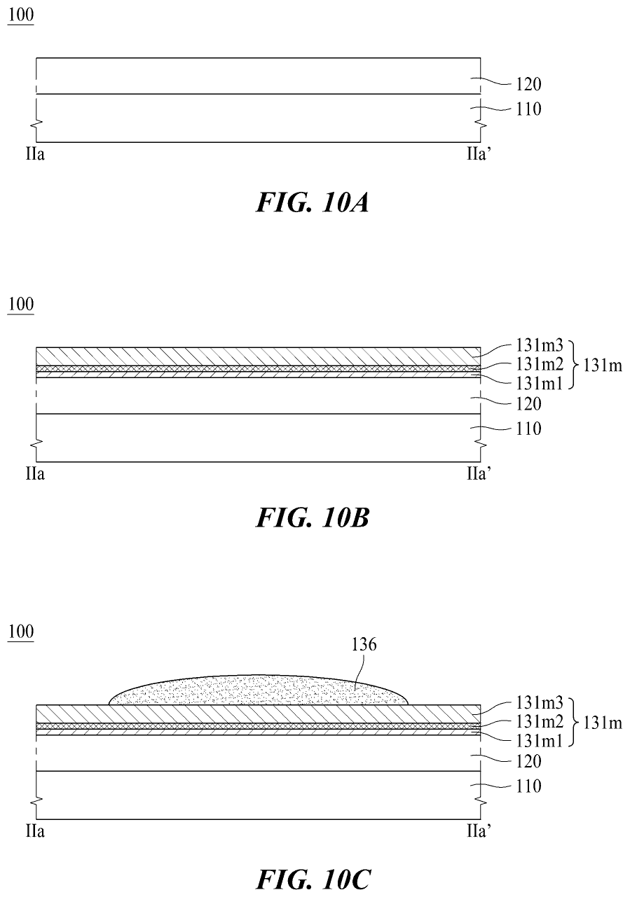

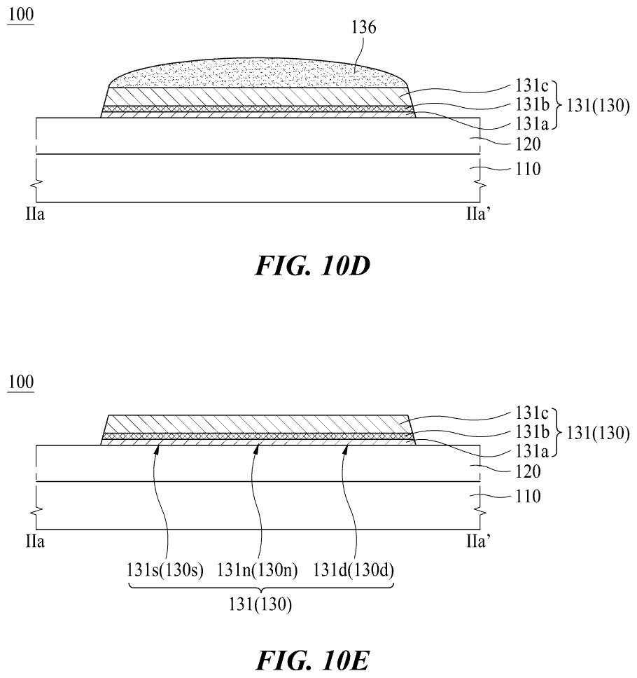

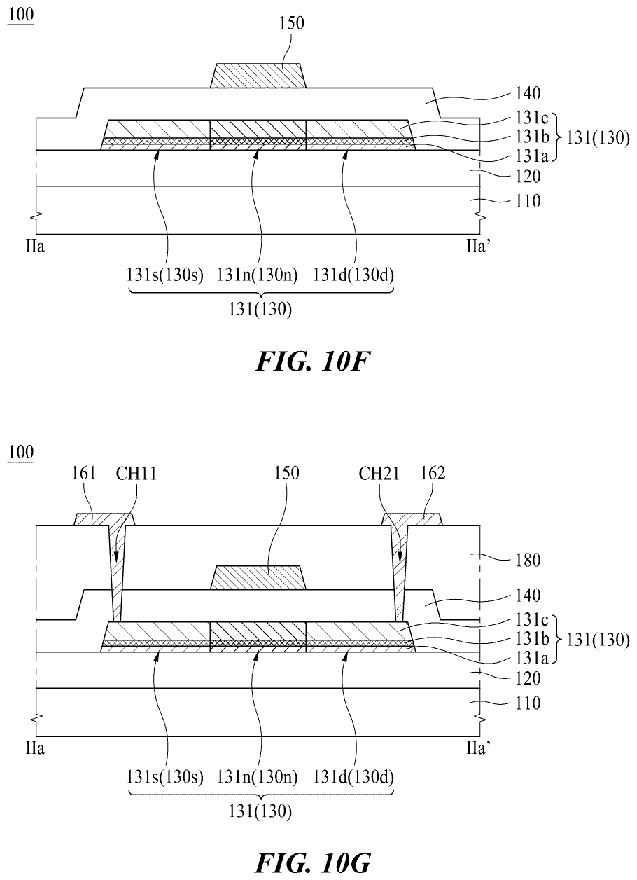

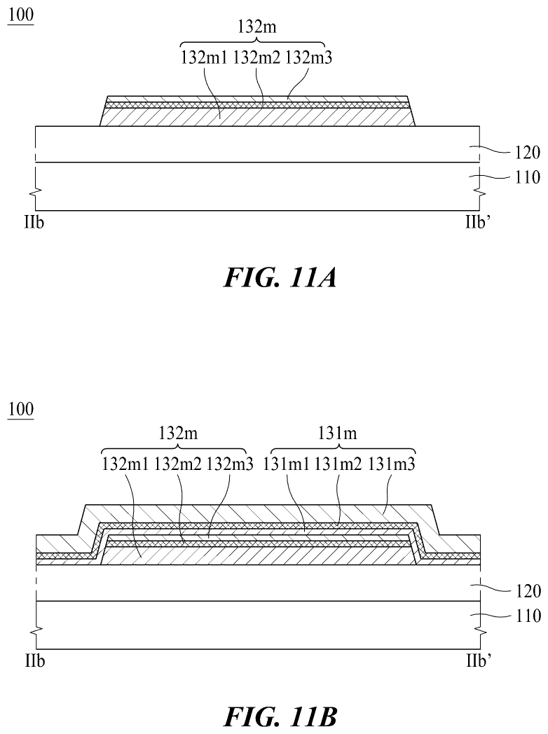

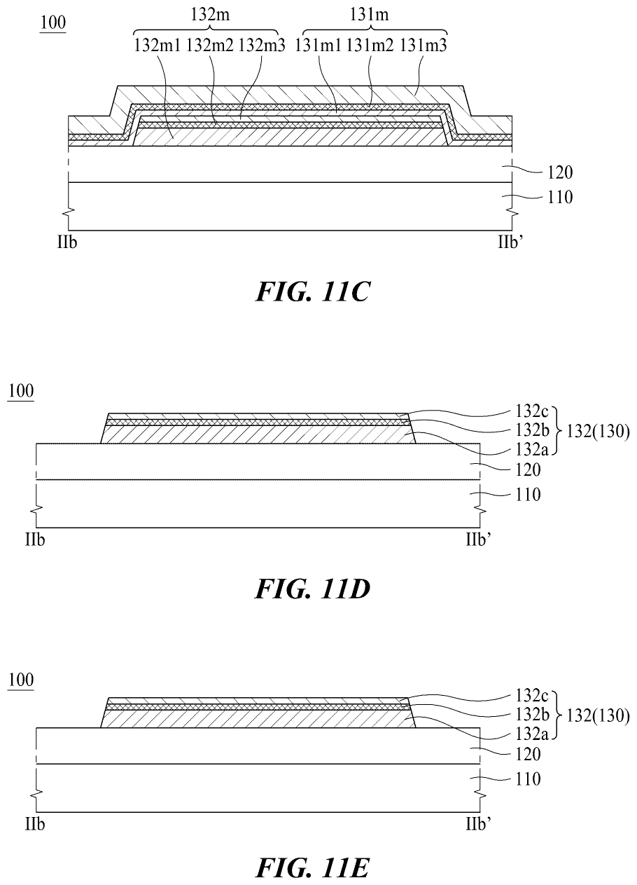

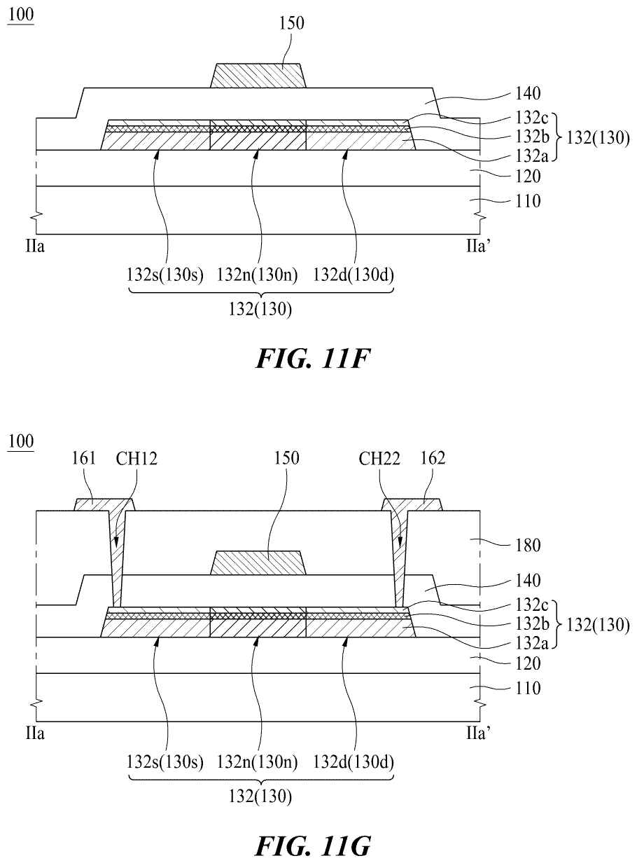

FIGS. 9A to 9G are plan views showing a manufacturing process of a thin film transistor 100 according to one embodiment of the present disclosure. FIGS. 10A to 10G are cross-sectional views showing a manufacturing process of a thin film transistor 100 according to one embodiment of the present disclosure. FIGS. 11A to 11G are cross-sectional views showing a manufacturing process of a thin film transistor 100 according to one embodiment of the present disclosure.

The cross-sectional views illustrated in FIGS. 10A to 10G may correspond to the cross-sectional views illustrated in FIG. 2. The cross-sectional views illustrated in FIGS. 11A to 11G may correspond to the cross-sectional views illustrated in FIG. 3.

Description of the configuration already explained above is omitted.

Referring to FIGS. 9A, 10A, and 11A, a base substrate 110 having a first area Area1 and a second area Area2 can be prepared. A first active layer 131 can be disposed in the first area Area1 of the base substrate 110, and a second active layer 132 can be disposed in the second area Area2.

Referring to FIG. 9A, FIG. 10A, and FIG. 11A, a buffer layer 120 may be formed on a base substrate 110. The buffer layer 120 may be formed across a first area Area1 and a second area Area2.

Referring to FIG. 9A, FIG. 10A, and FIG. 11A, after forming a second oxide semiconductor material layer 132m in a second area Area2 of a base substrate 110, the second oxide semiconductor material layer 132m may be etched. The step of forming the second oxide semiconductor material layer 132m may include a step of sequentially forming a second-first oxide semiconductor material layer 132m1, a second-second oxide semiconductor material layer 132m2, and a second-third oxide semiconductor material layer 132m3.

Referring to FIGS. 9B, 10B, and 11B, a first oxide semiconductor material layer 131m may be formed on a first area Area1 and a second area Area2. The step of forming the first oxide semiconductor material layer 131m may include a step of sequentially forming a first-first oxide semiconductor material layer 131m1, a first-second oxide semiconductor material layer 131m2, and a first-third oxide semiconductor material layer 131m3.

The first-second oxide semiconductor material layer 131m2 and the second-second oxide semiconductor material layer 132m2 may be formed of the first oxide semiconductor material. For example, the first oxide semiconductor material may include at least one of an IO (InO)-based oxide semiconductor material having an In concentration of 30% to 50% relative to the total concentration of In and O on an atomic basis, an IGZO (InGaZnO)-based oxide semiconductor material having an In concentration of 30% or more relative to the total concentration of In, Ga, and Zn on an atomic basis, a FIZO (FInZnO)-based oxide semiconductor material, a FIGZO (FeInGaZnO)-based oxide semiconductor material, and an IZO (InZnO)-based oxide semiconductor material.

The first-first oxide semiconductor material layer 131m1, the first-third oxide semiconductor material layer 131m3, the second-first oxide semiconductor material layer 132m1, and the second-third oxide semiconductor material layer 132m3 may be formed of a second oxide semiconductor material. For example, the second oxide semiconductor material may include at least one of an IGZO (InGaZnO)-based oxide semiconductor material having a concentration of In of less than 30% relative to the total concentration of In, Ga, and Zn on an atomic number basis, a GZTO (GaZnSnO)-based oxide semiconductor material, and a GZO (GaZnO)-based oxide semiconductor material.

Referring to FIG. 11B, in the second area Area2, the first oxide semiconductor material layer 131m may be disposed on the second oxide semiconductor material layer 132m. Specifically, the first oxide semiconductor material layer 131m may cover a side surface of the second oxide semiconductor material layer 132m.

Referring to FIG. 9C, FIG. 10C, and FIG. 11C, a photoresist pattern 136 may be formed on the first area Area1. For example, the photoresist pattern 136 may be disposed on the first oxide semiconductor material layer 131m. For example, the photoresist pattern 136 may be disposed on a portion of the upper surface of the first oxide semiconductor material layer 131m. For example, the photoresist pattern 136 is not disposed on the second area Area2. For example, the photoresist pattern 136 does not overlap with the second oxide semiconductor material layer 132m.

Referring to FIGS. 9D, 10D, and 11D, the first oxide semiconductor material layer 131m and the second oxide semiconductor material layer 132m can be simultaneously etched using the photoresist pattern 136 as a mask to form the first active layer 131 and the second active layer 132.

For example, referring to FIG. 10D, a first oxide semiconductor material layer 131m disposed in a first area Area1 may be etched using a photoresist pattern 136 as a mask to form a first active layer 131. Referring to FIG. 11D, a first oxide semiconductor material layer 131m and a second oxide semiconductor material layer 132m disposed in a first area Area1 and a second area Area2 may be simultaneously etched using a photoresist pattern 136 as a mask to form a second active layer 132.

Referring to FIG. 10D, the first active layer 131 may include a first oxide semiconductor layer 131a, a second oxide semiconductor layer 131b on the first oxide semiconductor layer 131a, and a third oxide semiconductor layer 131c on the second oxide semiconductor layer 131b. Referring to FIG. 11D, the second active layer 132 may include a fourth oxide semiconductor layer 132a, a fifth oxide semiconductor layer 132b on the fourth oxide semiconductor layer 132a, and a sixth oxide semiconductor layer 132c on the fifth oxide semiconductor layer 132b.

Referring to FIGS. 9E, 10E, and 11E, the photoresist pattern 136 disposed in the first area Area1 can be removed.

Referring to FIGS. 9F, 10F, and 11F, a gate insulating film 140 and a gate electrode 150 can be sequentially formed on the first active layer 131 and the second active layer 132. In addition, dopant ions can be doped into the first active layer 131 and the second active layer 132 using the gate electrode 150 as a mask. As a result, the first active layer 131 may include a first channel portion 131n, a first connecting portion 131s in contact with one side of the first channel portion 131n, and a second connecting portion 131d in contact with the other side of the first channel portion 131n, and the second active layer 132 may include a second channel portion 132n, a third connecting portion 132s in contact with one side of the second channel portion 132n, and a fourth connecting portion 132d in contact with the other side of the second channel portion 132n.

Since the first channel portion 131n and the second channel portion 132n are covered by the gate electrode 150, conductorization does not occur in the first channel portion 131n and the second channel portion 132n.

Since the first connecting portion 131s, the second connecting portion 131d, the third connecting portion 132s, and the fourth connecting portion 132d are not covered by the gate electrode 150, conductorization occurs in the first connecting portion 131s, the second connecting portion 131d, the third connecting portion 132s, and the fourth connecting portion 132d.

Referring to FIGS. 9G, 10G, and 11G, an interlayer insulating film 180, a source electrode 161, and a drain electrode 162 can be formed on the gate electrode 150. Descriptions of the interlayer insulating film 180, the source electrode 161, and the drain electrode 162 are omitted as they overlap with the preceding content.

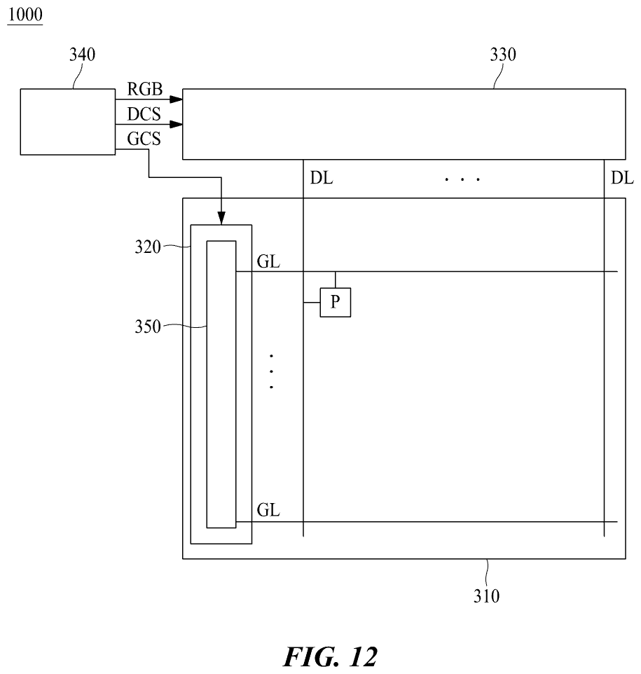

FIG. 12 is a schematic diagram illustrating a display apparatus 1000 according to further still another embodiment of the present disclosure.

As shown in FIG. 12, the display apparatus 1000 according to further still another embodiment of the present disclosure may include a display panel 310, a gate driver 320, a data driver 330 and a controller 340.

The display panel 310 includes gate lines GL and data lines DL, and pixels P are disposed in intersection areas of the gate lines GL and the data lines DL. An image is displayed by driving of the pixels P. The gate lines GL, the data lines DL and the pixels P may be disposed on the base substrate 110.

The controller 340 controls the gate driver 320 and the data driver 330.

The controller 340 outputs a gate control signal GCS for controlling the gate driver 320 and a data control signal DCS for controlling the data driver 330 by using a signal supplied from an external system not shown. Also, the controller 340 samples input image data input from the external system, realigns the sampled data and supplies the realigned digital image data RGB to the data driver 330.

The gate control signal GCS includes a gate start pulse GSP, a gate shift clock GSC, a gate output enable signal GOE, a start signal Vst and a gate clock GCLK. Also, control signals for controlling a shift register may be included in the gate control signal GCS.

The data control signal DCS includes a source start pulse SSP, a source shift clock signal SSC, a source output enable signal SOE and a polarity control signal POL.

The data driver 330 supplies a data voltage to the data lines DL of the display panel 310. In detail, the data driver 330 converts the image data RGB input from the controller 340 into an analog data voltage and supplies the data voltage to the data lines DL.

According to one embodiment of the present disclosure, the gate driver 320 may be packaged on the display panel 310. In this way, a structure in which the gate driver 320 is directly packaged on the display panel 310 will be referred to as a Gate In Panel (GIP) structure. In detail, in the Gate In Panel (GIP) structure, the gate driver 320 may be disposed on the base substrate 110.

The display apparatus 1000 according to one embodiment of the present disclosure may include the thin film transistor 100, 200 described above.

The gate driver 320 may include a shift register 350.

The shift register 350 sequentially supplies gate pulses to the gate lines GL for one frame by using the start signal and the gate clock, which are transmitted from the controller 340. In this case, one frame means a time period at which one image is output through the display panel 310. The gate pulse has a turn-on voltage capable of turning on a switching device (thin film transistor) disposed in the pixel P.

Also, the shift register 350 supplies a gate-off signal capable of turning off the switching device, to the gate line GL for the other period of one frame, at which the gate pulse is not supplied. Hereinafter, the gate pulse and the gate-off signal will be collectively referred to as a scan signal SS or Scan.

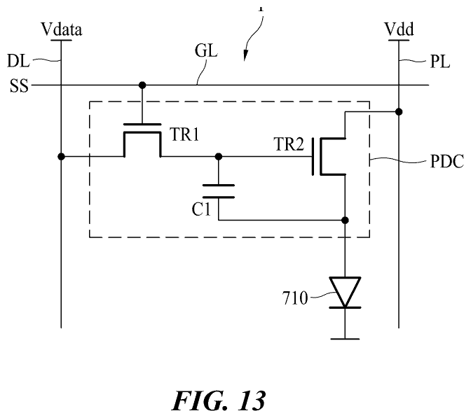

FIG. 13 is a circuit view illustrating any one pixel P of FIG. 12.

The circuit view of FIG. 13 is an equivalent circuit view for the pixel P of the display apparatus 1000 that includes an organic light emitting diode (OLED) as a display element 710.

Referring to FIG. 13, the pixel P includes a display element 710 and a pixel driving circuit PDC for driving the display element 710. In detail, the display apparatus 1000 according to one embodiment of the present disclosure may include a pixel driving circuit PDC on the base substrate 110.

The pixel driving circuit (PDC) of FIG. 13 includes a first thin film transistor (TR1) which is a switching transistor and a second thin film transistor (TR2) which is a driving transistor. The second thin film transistor (TR2) which is a driving transistor may include a thin film transistor 100, 200 according to the present disclosure.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls applying of the data voltage Vdata.

The driving power line PL provides a driving voltage Vdd to the display element 710, and the first thin film transistor TR1 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 320 through the gate line GL, the data voltage Vdata supplied through the data line DL is supplied to a gate electrode of the second thin film transistor TR2 connected to the display element 710. The data voltage Vdata is charged in a storage capacitor C1 formed between the gate electrode and a source electrode of the second thin film transistor TR2.

The amount of a current supplied to the organic light emitting diode (OLED), which is the display element 710, through the second thin film transistor TR2 is controlled in accordance with the data voltage Vdata, whereby a gray scale of light output from the display element 710 may be controlled.

The pixel drive circuit (PDC) according to another embodiment of the present disclosure may be formed in a variety of structures other than those described above. The pixel drive circuit (PDC) may include, for example, three or more thin film transistors.

According to the present disclosure, the following advantageous effects may be obtained.

A thin film transistor according to one embodiment of the present disclosure has a large s-factor in a period of threshold voltage and a large current value in the ON state by forming two active layers having different positions of a high mobility oxide semiconductor layer in a parallel structure with different widths.

The following paragraphs describe additional embodiments of a display apparatus.

In some embodiments, a display apparatus includes a light emitting diode and a thin film transistor (TFT) electrically connected to the light emitting diode. The thin film transistor may comprise a first active layer 131 and a second active layer 132 that are spaced apart from each other. The first active layer 131 may include a first oxide semiconductor layer 131a, a second oxide semiconductor layer 131b disposed on the first oxide semiconductor layer 131a, and a third oxide semiconductor layer 131c disposed on the second oxide semiconductor layer 131b. The second active layer 132 may include a fourth oxide semiconductor layer 132a, a fifth oxide semiconductor layer 132b disposed on the fourth oxide semiconductor layer 132a, and a sixth oxide semiconductor layer 132c disposed on the fifth oxide semiconductor layer 132b.

In some embodiments, the first and second active layers may have respective vertical thicknesses defined along a direction normal to a substrate surface. A lower portion of the first active layer 131, composed of the first and second oxide semiconductor layers, may occupy less than half of the total vertical thickness of the first active layer 131. Similarly, an upper portion of the second active layer 132, composed of the fifth and sixth oxide semiconductor layers, may occupy less than half of the total vertical thickness of the second active layer 132. This arrangement provides asymmetry in the vertical profile of the semiconductor stacks.

In some implementations, the thin film transistor further includes a gate electrode 150 formed over the first and second active layers. A gate insulating film 140 may be interposed between the gate electrode and the underlying active layers. The gate electrode may overlap both the second oxide semiconductor layer in the first active layer and the fifth oxide semiconductor layer in the second active layer. In such a configuration, the fifth oxide semiconductor layer is positioned vertically closer to the gate electrode than the second oxide semiconductor layer, enabling differential capacitive coupling between the two active layers and the gate electrode.

In a plan view of the display apparatus, the first and second active layers may be laterally spaced from one another across a direction transverse to the length of the gate electrode. The first active layer may have a greater width than the second active layer in the lateral direction separating the two active layers (e.g., the width (W1) of the first active layer 131 may be greater than the width (W2) of the second active layer 132). This dimensional asymmetry may be selected to optimize current distribution or electric field coupling in conjunction with the vertical structure.

In some embodiments, a source electrode may be electrically connected to one terminal end of both the first active layer and the second active layer, and a drain electrode may be electrically connected to an opposite terminal end of both the first and second active layers. The source and drain electrodes may be spaced apart along a longitudinal direction parallel to the length of the active layers. The first and second active layers may thus be connected in parallel between the source and drain electrodes, allowing current to flow through both active layers concurrently when the thin film transistor is in an on-state.

In one embodiment, the oxide semiconductor layers within each active layer may be arranged with thickness proportions that achieve desired electrical characteristics. For example, the sum of the thicknesses of the first and second oxide semiconductor layers may be within a range of 10% to 40% of the total vertical thickness of the first active layer. Likewise, the sum of the thicknesses of the fifth and sixth oxide semiconductor layers may be within 10% to 40% of the total thickness of the second active layer. This proportioning enables effective tuning of channel control and threshold voltage response in each active layer.

The first and second active layers may be configured to have different threshold voltages by varying their vertical structures and material compositions. As a result, the transfer characteristic of the thin film transistor—defined by its output current versus gate voltage curve—may exhibit a broadened threshold region compared to the response of either active layer operating alone. Such broadening of the threshold region may increase the effective subthreshold swing (s-factor) and improve gray scale control. In some embodiments, the light emitting diode is an organic light emitting diode (OLED) driven by current output from the thin film transistor. The broadened threshold region facilitates precise modulation of the OLED luminance in response to gate voltage variation.

According to some embodiments, a display apparatus includes a substrate, a plurality of gate lines extending in a first direction across the substrate, and a plurality of data lines extending in a second direction transverse to the first direction. Each intersection of a gate line and a data line may define a pixel region. Within each pixel region, a thin film transistor is disposed, including a first active layer and a second active layer laterally spaced apart from each other. Each active layer may comprise a multilayer oxide semiconductor stack that includes a high-mobility oxide semiconductor layer vertically interposed between two low-mobility oxide semiconductor layers.

A gate electrode may extend in the first direction and overlap both the first and second active layers. The transistor may also include a source electrode and a drain electrode, spaced apart and respectively connected to terminal ends of both active layers. A display element, such as a light emitting diode, may be disposed in each pixel region and electrically connected to the thin film transistor. The vertical position of the high-mobility layer in the second active layer may be closer to the gate electrode than the high-mobility layer in the first active layer, resulting in a difference in gate-field coupling between the two stacks.

In plan view, the lateral dimension of the first active layer may be greater than that of the second active layer in a direction separating the two stacks. This width asymmetry may be used to adjust relative current densities or capacitance coupling effects between the two active layers and the gate electrode.

In some embodiments, a gate insulating film is disposed between the gate electrode and the first and second active layers. The vertical spacing between the high-mobility layer in the second active layer and the gate insulating film may be within 3 nm, while the vertical spacing between the high-mobility layer in the first active layer and the gate insulating film may be at least 5 nm. This difference in spacing may be used to establish distinct electrostatic coupling profiles and threshold behaviors for each stack.

In certain implementations, the total thickness of the first active layer may be substantially equal to the total thickness of the second active layer. Maintaining equal thicknesses across the two stacks may support uniform film deposition, planarization, or contact alignment, while still achieving the desired asymmetry in internal layer placement and electrical performance.

In addition to the effects mentioned above, other features and advantages of the present disclosure are described below or may be clearly understood by those skilled in the art to which the present disclosure pertains from such description and explanation.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin film transistor comprising:
an active layer; and
a gate electrode overlapping at least a portion of the active layer,
wherein the active layer includes a first active layer and a second active layer which are spaced apart from each other,
wherein the first active layer includes:
a first oxide semiconductor layer;
a second oxide semiconductor layer on the first oxide semiconductor layer; and
a third oxide semiconductor layer on the second oxide semiconductor layer, and
wherein the second active layer includes:
a fourth oxide semiconductor layer;
a fifth oxide semiconductor layer on the fourth oxide semiconductor layer; and
a sixth oxide semiconductor layer on the fifth oxide semiconductor layer,
wherein a sum of a thickness of the first oxide semiconductor layer and a thickness of the second oxide semiconductor layer is 10% to 40% of a thickness of the first active layer, and
wherein a sum of a thickness of the fifth oxide semiconductor layer and a thickness of the sixth oxide semiconductor layer is 10% to 40% of a thickness of the second active layer.

2. The thin film transistor of claim 1, wherein the second oxide semiconductor layer has higher mobility than the first oxide semiconductor layer and the third oxide semiconductor layer, and the fifth oxide semiconductor layer has higher mobility than the fourth oxide semiconductor layer and the sixth oxide semiconductor layer.

3. The thin film transistor of claim 2, wherein a mobility of the second oxide semiconductor layer and the fifth oxide semiconductor layer are 20 cm²/V·s to 100 cm²/V·s.

4. The thin film transistor of claim 2, wherein a mobility of the first oxide semiconductor layer, the third oxide semiconductor layer, the fourth oxide semiconductor layer, and the sixth oxide semiconductor layer are 5 cm²/V·s to 15 cm²/V·s.

5. The thin film transistor of claim 1, wherein the second oxide semiconductor layer and the fifth oxide semiconductor layer are each made of a first oxide semiconductor material, and
wherein the first oxide semiconductor material includes at least one of an IO (InO)-based oxide semiconductor material having an In concentration of 30% to 50% relative to a total concentration of In and O on an atomic basis, an IGZO (InGaZnO)-based oxide semiconductor material having an In concentration of 30% or more relative to a total concentration of In, Ga, and Zn on an atomic basis, a FIZO (FInZnO)-based oxide semiconductor material, a FIGZO (FeInGaZnO)-based oxide semiconductor material, and an IZO (InZnO)-based oxide semiconductor material.

6. The thin film transistor of claim 1, wherein the first oxide semiconductor layer, the third oxide semiconductor layer, the fourth oxide semiconductor layer, and the sixth oxide semiconductor layer are each formed of a second oxide semiconductor material, and
wherein the second oxide semiconductor material includes at least one of an IGZO (InGaZnO)-based oxide semiconductor material having an In concentration of less than 30% relative to the total concentration of In, Ga, and Zn on an atomic basis, a GZTO (GaZnSnO)-based oxide semiconductor material, and a GZO (GaZnO)-based oxide semiconductor material.

7. The thin film transistor of claim 1, wherein the first active layer includes:
a first channel portion overlapping the gate electrode;
a first connecting portion at one lateral side of the first channel portion; and
a second connecting portion at an opposite lateral side of the first channel portion, and
when a direction of a straight line connecting the first connecting portion and the second connecting portion at the shortest distance is a first direction and a direction perpendicular to the first direction is a second direction, a width of the first active layer is greater than a width of the second active layer based on the second direction.

8. The thin film transistor of claim 1, wherein a thickness of the second oxide semiconductor layer is greater than a thickness of the fifth oxide semiconductor layer.

9. The thin film transistor of claim 8, wherein the thickness of the second oxide semiconductor layer is 3 nm or more and less than 5 nm, and
wherein the thickness of the fifth oxide semiconductor layer is 2 nm or more and less than 3 nm.

10. The thin film transistor of claim 7, wherein the first active layer and the second active layer are each disposed to extend along the first direction and are spaced apart from each other along the second direction.

11. The thin film transistor of claim 1, wherein a shortest distance between the gate electrode and the fifth oxide semiconductor layer is shorter than a shortest distance between the gate electrode and the second oxide semiconductor layer.

12. The thin film transistor of claim 1, further comprising a source electrode and a drain electrode, which are disposed spaced apart from each other and each connected to the active layer, and
wherein a shortest distance between the source electrode and the fifth oxide semiconductor layer is shorter than a shortest distance between the source electrode and the second oxide semiconductor layer.

13. The thin film transistor of claim 12, wherein a shortest distance between the drain electrode and the fifth oxide semiconductor layer is shorter than a shortest distance between the drain electrode and the second oxide semiconductor layer.

14. A method for manufacturing a thin film transistor comprising:
steps of preparing a base substrate having a first area and a second area;
forming a second oxide semiconductor material layer on the second area, and then etching the second oxide semiconductor material layer;
forming a first oxide semiconductor material layer on the first area and the second area;
forming a photoresist pattern on the first area;
simultaneously etching the first oxide semiconductor material layer and the second oxide semiconductor material layer using the photoresist pattern as a mask to form a first active layer and a second active layer; and
forming a gate electrode on the first active layer and the second active layer.

15. The method for manufacturing a thin film transistor of claim 14, wherein the first oxide semiconductor material layer is disposed on the second oxide semiconductor material layer and cover a side surface of the second oxide semiconductor material layer.

16. The method for manufacturing a thin film transistor of claim 14, wherein the photoresist pattern is not disposed on the second area.

17. The method for manufacturing a thin film transistor of claim 14, wherein the first active layer includes:
a first oxide semiconductor layer;
a second oxide semiconductor layer on the first oxide semiconductor layer; and
a third oxide semiconductor layer on the second oxide semiconductor layer, and
the second active layer includes:
a fourth oxide semiconductor layer;
a fifth oxide semiconductor layer on the fourth oxide semiconductor layer; and
a sixth oxide semiconductor layer on the fifth oxide semiconductor layer, and
wherein a sum of a thicknesses of the first oxide semiconductor layer and the second oxide semiconductor layer is 10% to 40% of a thickness of the first active layer, and
wherein a sum of a thicknesses of the fifth oxide semiconductor layer and the sixth oxide semiconductor layer is 10% to 40% of a thickness of the second active layer.

18. The method for manufacturing a thin film transistor of claim 17, wherein a shortest distance between the gate electrode and the fifth oxide semiconductor layer is shorter than a shortest distance between the gate electrode and the second oxide semiconductor layer.

19. The method for manufacturing a thin film transistor of claim 17, further includes a step of forming a source electrode and a drain electrode, which are spaced apart from each other and respectively connected to the active layer,
wherein a shortest distance between the source electrode and the fifth oxide semiconductor layer is shorter than a shortest distance between the source electrode and the second oxide semiconductor layer.

20. A display apparatus comprising:
a light emitting diode;
a thin film transistor electrically connected to the light emitting diode, the thin film transistor including:
a first active layer including:
a first oxide semiconductor layer;
a second oxide semiconductor layer on the first oxide semiconductor layer; and
a third oxide semiconductor layer on the second oxide semiconductor layer,
a second active layer spaced apart from the first active layer, the second active layer including:
a fourth oxide semiconductor layer;
a fifth oxide semiconductor layer on the fourth oxide semiconductor layer; and
a sixth oxide semiconductor layer on the fifth oxide semiconductor layer,
wherein, in the first active layer, a lower portion comprising the first and second oxide semiconductor layers occupies less than half of a vertical thickness of the first active layer, and
wherein, in the second active layer, an upper portion comprising the fifth and sixth oxide semiconductor layers occupies less than half of a vertical thickness of the second active layer.

21. The display apparatus of claim 20, wherein the thin film transistor further includes a gate electrode on the first active layer and the second active layer with a gate insulating film interposed therebetween,
wherein the gate electrode is on the fifth oxide semiconductor layer in the second active layer and the second oxide semiconductor layer in the first active layer, with the fifth oxide semiconductor layer vertically closer to the gate electrode than the second oxide semiconductor layer.

22. The display apparatus of claim 20, wherein, in a plan view, the first active layer has a greater width than the second active layer in a direction laterally separating the first and second active layers.

23. The display apparatus of claim 20, wherein a source electrode is electrically connected to one end of both the first active layer and the second active layer, and a drain electrode is electrically connected to an opposite end of both the first active layer and the second active layer,
the source and drain electrodes being spaced apart from each other along a longitudinal axis of the active layers,
wherein the first active layer and the second active layer are connected in parallel between the source electrode and the drain electrode, such that current flows through both active layers concurrently when the thin film transistor is turned on.

24. The display apparatus of claim 20, wherein a sum of a thickness of the first oxide semiconductor layer and a thickness of the second oxide semiconductor layer is 10% to 40% of a thickness of the first active layer, and
wherein a sum of a thickness of the fifth oxide semiconductor layer and a thickness of the sixth oxide semiconductor layer is 10% to 40% of a thickness of the second active layer.

25. The display apparatus of claim 20, wherein the first active layer and the second active layer are configured to exhibit different threshold voltages, such that a transfer characteristic of the thin film transistor includes a broadened threshold region relative to either active layer individually, and
wherein the light emitting diode is an organic light emitting diode driven by a current output of the thin film transistor, and the broadened threshold region enabling fine control of luminance in the organic light emitting diode.

26. A display apparatus comprising:
a substrate;
a plurality of gate lines extending along a first direction on the substrate;
a plurality of data lines extending along a second direction transverse to the first direction, wherein each intersection of a gate line and a data line defines a pixel region;
a thin film transistor disposed in each pixel region and including:
a first active layer and a second active layer laterally spaced apart, each comprising a multilayer oxide semiconductor stack including a high-mobility layer vertically interposed between two low-mobility layers;
a gate electrode extending in the first direction and overlapping both the first and second active layers; and
a source electrode and a drain electrode spaced apart and electrically connected to terminal ends of both active layers; and
a display element disposed in the pixel region and electrically connected to the thin film transistor,
wherein the high-mobility layer in the second active layer is vertically positioned closer to the gate electrode than the high-mobility layer in the first active layer.

27. The display apparatus of claim 26, wherein, in a plan view, the first active layer has a greater width than the second active layer.

28. The display apparatus of claim 26, further comprising a gate insulating film interposed between the gate electrode and the first and second active layers,
wherein the high-mobility layer in the second active layer is located within 3 nm of the gate insulating film, and the high-mobility layer in the first active layer is located at least 5 nm from the gate insulating film.

29. The display apparatus of claim 26, wherein the total thickness of the first active layer is equal to the total thickness of the second active layer.
